(19) United States
(12) Patent Application Publication
(10) Pub. No.: US 2026/0353126 A1
(43) Pub. Date: Nov. 5, 2026

(54) Achieving High Spectral Resolution in Machine Diagnostics Beside Changing Speed

(71) Applicant: Siemens Aktiengesellschaft, Muenchen (DE)

(72) Inventors: Gabor LADANYI, Budapest (HU); Bence NEMET, Budapest (HU); Gábor NYIRI, Budapest (HU)

(21) Appl. No.: 19/488,125

(22) PCT Filed: May 23, 2024
(86) PCT No.: PCT/EP2024/064218

§ 371 Date: Nov. 26, 2025

(30) Foreign Application Priority Data
May 31, 2023 (EP) 23176291.5

(51) Int. Cl. H04W 24/08

(52) U.S. Cl. CPC H04W 24/08

(57) ABSTRACT

A method for analyzing a machine arrangement includes comprises obtaining N time domain measurement samples at times T(n) in which n extends over the number of samples N and the distance between neighboring samples in time domain is T, determining updated, normalized time domain measurement samples based on adapting a timing T_{adapt}(n) of each sample based on the associated T(n) and T, based on an actual frequency factual(n) of the machine arrangement, and further based on an undesirable behavior and/or error correlated frequency F, determining M recreated, normalized time domain measurement samples at times T(m) with a constant sampling period T2 in which m extends over the number of samples M, and performing frequency analysis on the recreated time domain measurement samples.

### CROSS-REFERENCE TO RELATED APPLICATIONS

This is a U.S. national stage of application No. PCT/EP2024/064218 filed 23 May 2024. Priority is claimed on European Application No. 23176291.5 filed 31 May 2023, the content of which is incorporated herein by reference in its entirety.

### BACKGROUND OF THE INVENTION

### 1. Field of the Invention

The present invention relates to a computer program product, storage medium, electronic control device, a machine arrangement and to a method of analyzing the machine arrangement or its operation.

### 2. Description of the Related Art

In the course of machine diagnostics, Fast Fourier Transform (FFT) is a method to analyze time domain measurements, which may comprise a number of samples taken over time, such as at constant frequency and/or periodically with the same time domain gap between all samples. To perform a successful analysis in the frequency domain, appropriate frequency resolution is needed, e.g., when the diagnostic method is vibrational or a motor current analysis. High resolution in the frequency domain can be gained with a long-time measurement of the signal. During this measurement, the speed or the supply frequency of the motor should be constant. In cases in which the speed is not constant, for example, when the speed is controlled by a (proportional-integral-derivative (PID) controller, high resolution spectral analysis can be performed, but the spectrum may be faded.

EP 4 040 135 A1 discloses a diagnostic device and a respective method for detecting a state of a machine, where the machine is operated with various rotational speeds and where a diagnosis is based on resampling a signal generated by a measuring unit.

U.S. Pub. No. 2022/0187165 A1 further describes a method with which a time-dependent measurement signal can be corrected, where the corrected measurement signal is utilized for motor transmission fault detection.

Additionally, U.S. Pub. No. 2015/0316593 A1 shows the processing of an analog signal into digital data. The processing is conducted via two conversion units converting the signal utilizing different sample rates.

Furthermore, KR 2011 0046754 A discloses an apparatus with which a sampled signal of an analog-to-digital converter can be down-sampled.

### SUMMARY OF THE INVENTION

In view of the foregoing, it is an object of the invention to provide an improved technique for providing high-resolution frequency analysis for machine arrangements operated with varying speed.

This and other objects and advantages are achieved in accordance with the invention by a method for analyzing a machine arrangement and/or operation thereof, where the method may be performed by an electronic control device and/or circuitry, in particular processing circuitry. The method comprises obtaining N time domain measurement samples at times T(n) pertaining to operation of the machine arrangement. The operating machine arrangement has a typical (also referred to as reference) frequency F, where n extends over the number of samples N and the distance between neighboring samples in time domain is T.

The method also comprises determining updated time domain measurement samples based on adapting a timing T_{adapt}(n) of each sample based on the associated T(n) and/or T, based on an actual frequency f_{actual}(n) of the analyzed machine arrangement associated to the timing T(n) and/or T_{adapt}(n), and further based on F, with F being a frequency correlated with an occurrence of an undesirable behavior and/or at least one error of the machine arrangement and with the updated time domain measurement samples being normalized time domain measurement samples. Moreover, the method comprises determining M recreated time domain measurement samples from the normalized time domain measurement samples at times T(m) with a constant sampling period T2, where m extends over the number of samples M and where M>N and/or T2 is shorter than T. The method also comprises performing frequency analysis on the recreated time domain measurement samples. The method may comprise performing error analysis and/or controlling the machine arrangement based on the frequency analysis, e.g., increasing or decreasing speed, and/or performing a stop, and/or providing a warning indication, e.g., to an operator, which may be based on an error analysis or diagnosis.

M, N may be integer values larger than 1. M may be at least or equal to 1.2 times N, or at least or equal to 1.5 times N, or at least or equal to 2 times N. M may be dependent on the smallest and/or largest and/or average f_{actual}(n). The M samples may in general be based on estimation and/or interpolation of sample values for the M recreated, normalized time domain measurement samples, e.g., based on the measurement samples and/or their values obtained. This may provide equidistant samples (in time domain), e.g., for frequency analysis like in an FFT.

The method may comprise and/or facilitate identifying, in the frequency analysis, irregular peaks in frequency domain with good/optimal resolution even if the operational speed of the machine arrangement changes, e.g., changes significantly over the time horizon of the frequency analysis.

It may be considered that the updated time domain measurement samples may be determined based on, and/or utilizing, T_{adapt}=T*f_{actual}/F. This may allow producing samples that have a quasi-reference shape, e.g., according to typical operation at frequency F. Tadapt may indicate the length of time between two neighboring samples of the updated samples (sampling interval). In order to calculate the sample position in time, sequential arrangement of the intervals may be considered, in particular considering T(n), e.g., for all n smaller than the current n. Different sampling interval T_{adapt} may have different durations, e.g., depending on the actual frequency using for adapting. The expression T_{adapt}(n) may be used to indicate the associated samples and/or different sampling intervals.

It may be considered that f lies in an operational range of frequencies of the machine arrangement. This may provide a suitable reference, in particular in the system with essentially harmonic behavior. However, cases in which F may be outside an operational range may be considered, e.g., depending on waveform. The operational range may describe the range of frequencies at which the machine arrangement or component to be analyzed usually is operated and/or driven, and/or may be driven or operated.

In some cases, F may be 50 Hz. The machine arrangement may be driven with AC current, which may have a frequency of 50 Hz. This may represent a suitable reference for such systems, if this frequency correlates with an occurrence of an undesirable behavior and/or errors.

The samples may indicate a current (e.g., amplitude and/or phase), and/or voltage, and/or speed (e.g., rotational speed), and/or vibrational amplitude. Such parameters may be suitable for frequency analysis. These parameters may reflect erroneous and/or undesirable effects occurring during operation.

The method may be performed conditioned on an acceleration threshold or speed change threshold being reached by the machine arrangement. If there is a small change in speed and/or acceleration (lower than the threshold), then the frequency analysis may be performed on the obtained time domain measurement samples, without determining adapted timing and/or normalized samples. This may lower processing requirements. The acceleration and/or speed change may be determined based on measurements, e.g., as provided by an inverter and/or rotational speed sensor and/or current sensor and/or other sensor, and/or determined based on the time domain measurement samples, and/or based on control signaling received, e.g., from circuitry controlling the speed or acceleration. The acceleration and/or speed change may pertain to a specific time interval and/or sample number, e.g., covering a FFT window, or parts thereof.

It may generally be considered that the machine arrangement may operate at varying or changing speed. The speed may be controlled by circuitry, e.g., a PID and/or electronic circuitry, e.g., in accordance with a program and/or operator input. Frequency analysis with good/optimal resolution may be provided even in such cases. It may be considered that the machine arrangement is operated at different speeds and/or frequencies (e.g., next to and/or including F), e.g., scanning and/or analyzing frequency behavior over a speed and/or frequency range; this may be part of the method. Thus, difficult-to-detect effects may be detected, e.g., a presence of a resonance, such as at a border of an operational range. The machine arrangement may comprise a rotational element such as a rotor, motor or generator. Such elements may represent a component of the arrangement, and may be particularly for the proposed analysis due to their normally harmonic or quasi-harmonic operation.

In some embodiments, the machine arrangement may comprise an AC (Alternating Current) machine, and/or may be driven by three-phase current, where the samples may represent a current amplitude. In such cases, the current may be easy to measure, while being indicative of operational conditions of the driven component or motor or machine.

Performing frequency analysis may in general comprise performing a Fast Fourier Transform of the recreated, normalized time domain measurement samples. Other forms of frequency domain transformation may be considered, e.g., other forms of Discrete Fourier Transforms. This may allow a reliable frequency domain representation, which may be highly indicative of operational behavior, in particular potential errors.

The objects and advantages are also achieved in accordance with the invention by a computer program product comprising program code that causes processing circuitry and/or a computer to perform the method described herein. The computer and/or processing circuitry may represent, and/or be part of, an electronic control device.

The objects and advantages are further achieved in accordance with the invention by a storage medium storing a computer program product as described herein. The storage medium may comprise and/or be implemented as one or more memories and/or have different parts or components of the program product stored on different memories or media. The storage medium may be non-transitory.

The objects and advantages are also achieved in accordance with the invention by an electronic control device comprising processing circuitry. The electronic control device is adapted to perform the method as described herein. In particular, the processing circuitry may be configured to perform one or more actions of the method. The device and/or circuitry may comprise one or more components and/or may be a distributed, e.g., interconnected via suitable communication interfaces. Different components may perform different actions, e.g., based on exchanging information via the interface/s. The electronic control device may be and/or comprise one or more computers and/or controllers and/or processing circuitries.

The objects and advantages are still further achieved in accordance with the invention by a machine arrangement comprising an electronic control device as described herein. The machine arrangement may be controlled and/or monitored (e.g., based on performing frequency analysis) by the electronic control device.

In general, the duration of an interval in time domain between two samples may be considered a sampling interval or sampling period, which may be referenced as T. The N time domain measurement samples may be sampled with a constant sampling period T and/or may be sampled periodically, and/or with a sampling frequency fr. In general, there may be one fewer interval than samples for each group of measurement samples.

Obtaining measurement samples may comprise performing measurements and/or receiving measurement information and/or the samples, e.g., from one or more sensors and/or sensor arrangements and/or measurement devices. A frequency may correspond to representation or parametrization of a frequency (e.g., rotational or vibrational frequency) and/or speed, e.g., rotational speed or a velocity).

A typical frequency or reference frequency may be dependent on a waveform occurring during operation of the machine arrangement (e.g., used to drive operation), and/or a frequency range of operation, and/or operational conditions of the machine arrangement. It may be a frequency most commonly or typically occurring during operation. The measurement samples may pertain and/or be representable in frequency domain, and/or may include the typical frequency.

Analyzing the machine arrangement and/or operation of the machine arrangement may pertain to a specific component of the machine arrangement, in particular one with movable and/or vibrating and/or rotating part/s, e.g., a rotor and/or motor and/or generator and/or actuator. The speed or frequency of operation may pertain to a specific operational parameter of the machine arrangement and/or the component or its part, e.g., a rotational speed of the rotor of a motor or generator, and/or vibrational frequency of a machine. A machine arrangement may comprise a machine and/or motor; a motor may drive a machine. A machine may comprise a robot arm and/or manufacturing or processing device and/or pump.

Frequency analysis may in some cases be performed pertaining to a component, such as a motor and/or a machine.

An actual frequency f_{actual}(n) may be a frequency of the analyzed machine arrangement, and/or of its operation. It may be a frequency measured and/or determined during operation of the machine arrangement and/or pertaining to the component to be analyzed. The actual frequency may be associated to the timing T(n) and/or T_{adapt}(n) in that it may be representative of the frequency at and/or close to this time/these times. In some cases, the actual frequency may be measured coincident in time domain with the obtained time domain sample T(n). To each sample and/or sampling interval, there may be associated an actual frequency, which may differ between samples and/or sampling intervals. The actual frequency may be based on measurement and/or interpolation and/or estimation. Measurement may in particular be based on a current and/or an inverter or inverter current and/or optical and/or acoustic and/or force-based measurements of a moving and/or rotational component of a machine arrangement.

The method may especially be performed, completely or in part, by an electronic execution device such as a computer system. To these ends, the method may be formulated as a computer program product with program code. The above described system or arrangement may comprise the computer system.

Other objects and features of the present invention will become apparent from the following detailed description considered in conjunction with the accompanying drawings. It is to be understood, however, that the drawings are designed solely for purposes of illustration and not as a definition of the limits of the invention, for which reference should be made to the appended claims. It should be further understood that the drawings are not necessarily drawn to scale and that, unless otherwise indicated, they are merely intended to conceptually illustrate the structures and procedures described herein.

### BRIEF DESCRIPTION OF THE DRAWINGS

The above-described properties, features and advantages of present invention as well as the way they are achieved will be made clearer and better understandable in the light of the following discussion, making reference to exemplary embodiments shown in accompanying figures, in which:

FIG. 1 shows an exemplary machine arrangement with current based analysis in accordance with the invention;

FIG. 2 shows a graphical plot of faded spectral features in cases of speed change for another exemplary machine arrangement;

FIG. 3 shows graphical plots of a desired frequency spectrum in cases of speed change;

FIG. 4 shows a flow diagram of a method in accordance with the invention;

FIG. 5 shows an exemplary diagram of obtained time domain measurement samples;

FIG. 6 shows an exemplary diagram of updated, normalized time domain samples;

FIG. 7 shows an exemplary diagram of recreated, normalized time domain samples;

FIG. 8 shows an exemplary diagram of a case of speed change during operation;

FIG. 9 shows an exemplary diagram of frequency analysis performed based on the data of FIG. 8; and

FIG. 10 shows an exemplary diagram frequency analysis performed based on the data of FIG. 8 according to the invention.

### DETAILED DESCRIPTION OF THE EXEMPLARY EMBODIMENTS

In the Figures, analysis of a machine arrangement comprising a motor driven by a current is described by way of example. Other ways parameters than current for frequency analysis may be considered. In general, the frequency of the peaks appearing in frequency spectrum and potentially indicating different errors may be proportional to the rotating frequency. In Motor Current Signature Analysis (based on current supplied to a motor), the approaches may be used as well, e.g., if the motor is synchronous, or an induction motor; the changing of slip may be considered negligible. In the examples, a typical or reference frequency F of 50 Hz is used. For different applications, a different reference frequency may be used, depending on use case, machine arrangement and/or operational conditions.

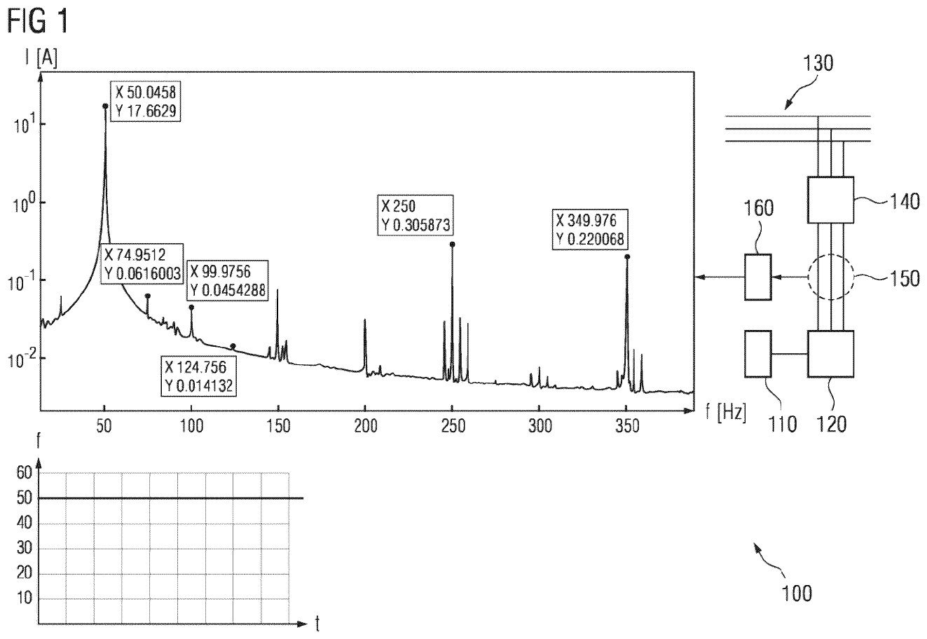

FIG. 1 shows an exemplary machine arrangement 100, e.g., in accordance with the invention. The machine arrangement 100 comprises a machine 110, which is driven by a motor 120, which may be AC driven. The motor 120 is provided with current via a three-phase current supply 130. The current is supplied by the current supply 130 to a current control device 140, which may be a synchronization device or inverter, depending on the motor type. From the device 140, current is provided to the motor 120. A sensor arrangement 150 provides measurement samples of the current amplitude/s to an electronic control device 160, which performs analysis of operation of the machine arrangement 100, represented by the motor 120. The analysis provided is seen as current (I) over frequency (f) spectrum.

At constant speed of around 50 Hz (as evident in the diagram at the left lower corner showing frequency f over time t), a clear maximum peak appears at 50 Hz in the frequency domain representation after performing a FFT. Several other, smaller peaks can be seen, which may indicate potential error sources. The frequency of the peaks may be assumed to be proportional to the speed of a synchronous motor, and, e.g., if the change of slip is negligible, of an induction motor. These peaks refer to specific errors. Consequently, the frequency of 50 Hz correlates with an occurrence of an undesirable behavior (e.g. vibrations that could cause damages if persisting for a longer time etc.) and/or errors of the machine arrangement 100. If an inverter 140 drives the motor 120 with constant speed, then the Motor Current Signature Analysis can be used in the same manner, provided the supply frequency does not change.

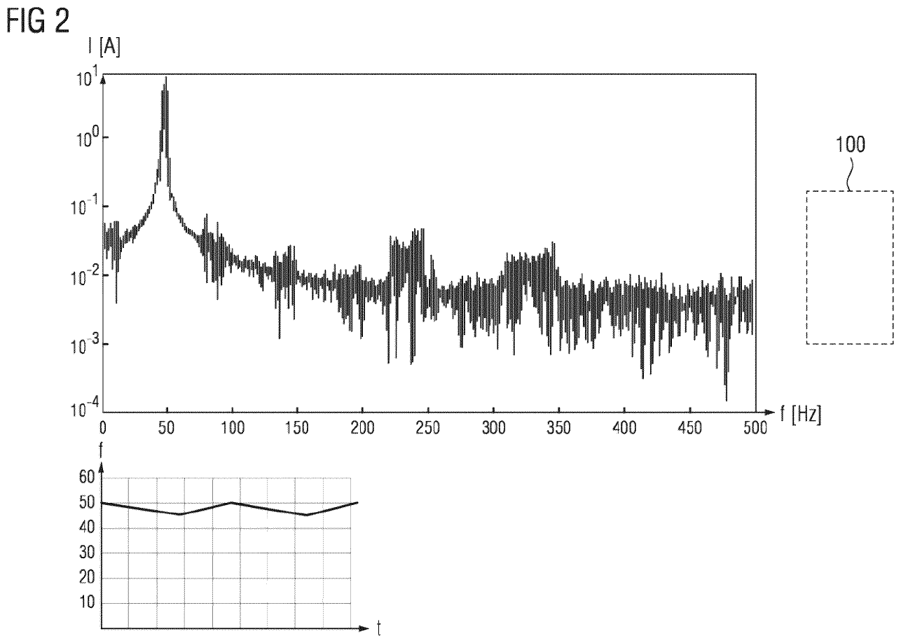

FIG. 2 shows an example with the same machine arrangement 100 (only indicated by reference number), with a motor 120 operated at varying speeds, as indicated by the changing frequency in the diagram f-over-t in the lower left corner. If the device 140, e.g., an inverter, drives the motor 120 with varying speed, one of the following may occur: when using long measuring times to achieve good resolution, peaks fade, and cannot be used efficiently for error analysis (as shown in FIG. 2); when using short measurement times at almost constant speed, bad resolution may result, which may also lead to insufficient or unusable frequency analysis.

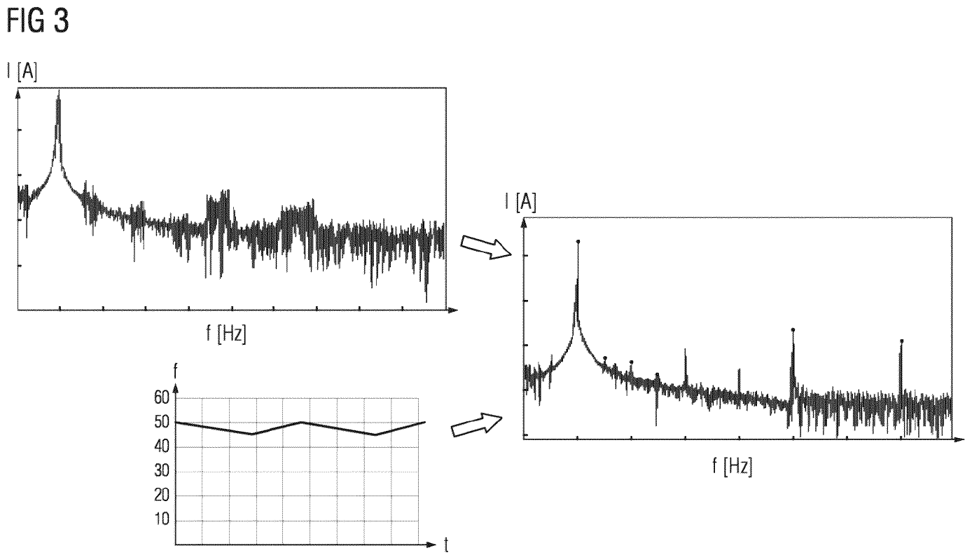

It is proposed to provide a frequency spectrum similar to the spectrum received at reference frequency (here 50 Hz) with fixed speed, where the reference frequency correlates with an occurrence of an undesirable behavior and/or errors of the machine arrangement 100. This is shown in FIG. 3, with a frequency spectrum for varying speed with unclear peaks being transformed to a spectrum with clearly identified peaks, with what may be referred to as “50 Hz normalized frequency spectrum”.

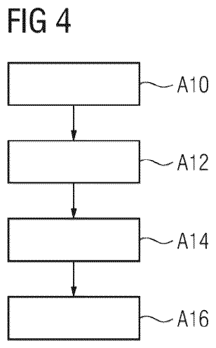

FIG. 4 shows an exemplary flow diagram in accordance with the invention. The method of analyzing a machine arrangement 100 comprises an action A10 of obtaining N time domain measurement samples (also referred to as original samples or originally obtained samples) at times T(n) pertaining to operation of the machine arrangement 100, with a typical frequency F of the operating machine arrangement 100, where the frequency F correlates with an occurrence of an undesirable behavior and/or errors of the machine arrangement 100. n is an integer or zero, which extends over the number of samples N, such that all N samples and/or gaps between samples may be referenced. For example, n may extend from 0, 1, 2, . . . to N- 1 (m may be analogous with reference to M). It may be considered that in general, each sample represents a position in time domain and a parameter value (in at least one other dimension, e.g., if scalar or representing a vector). The distance (duration or length of the time domain interval) between neighboring samples in time domain is T.

The method comprises an action A12 of determining updated time domain measurement samples (also referred to as updated samples) based on adapting a timing T_{adapt}(n) of each sample based on the associated T(n) and/or T, further based on an actual frequency f_{actual}(n) of the analyzed machine arrangement (100) associated to the timing T(n) and/or T_{adapt}(n), and further based on F. Thus, T(n) may be mapped to T_{adapt}(n) for each n. In particular, it may hold T_{adapt}(n)=T* f_{actual}(n)/F, or T_{adapt}(n)=f (T(n))*f_{actual}(n)/F. This may produce a spectrum similar to a constant speed spectrum by changing the time basis. A timing may generally indicate a position in time domain and/or a time interval duration, e.g., between two time domain positions of samples, which may be neighboring. f(T(n)) may represent a function of T(n), e.g., T(n)−T(n−1), or similar, for cases in which T(n) represent a time domain location of sample n. The updated time domain measurement samples are normalized time domain measurement samples.

Moreover, the method comprises an action A14 of determining M recreated time domain measurement samples at times T(m) with a constant sampling period T2 from the normalized time domain measurement samples, where m extends over the number of samples M. M is larger than N, but it is also possible that T2 may be shorter than a sampling period T based on which the samples originally are obtained. It should be noted that T2 may be considered an adapted and/or manufactured and/or virtual sampling period T2, which may be the basis for an input for frequency analysis, which may require evenly-space samples in time domain.

The recreated, normalized samples may have values (in their other dimension/s than time) determined based on interpolation based on the sample values of the updated and/or originally obtained samples. The recreated, normalized time domain measurement samples may be shifted in time domain relative to the originally obtained samples, and shifted in their values (in the other dimension/s). It may be considered that one or more of the original samples are not included in the recreated, normalized time domain measurement samples.

In an action A16, frequency analysis is performed on, and/or based on, the M recreated, normalized time domain measurement samples.

In general, the machine arrangement may be controlled to operate a varying and/or changing speed, e.g., due to operational conditions, and/or to scan a frequency range for hard-to-detect effects. For example, a machine arrangement, such as a pump, may be controlled to operate at different frequencies in an operational range, which in analysis may provide information (e.g., a peak) at a frequency that would not appear during operation at a typical frequency. In an exemplary scenario, a pump may have a resonance, e.g., at a lower edge of 35 Hz in an operational range between 30 Hz and 50 Hz, or 30 Hz and 70 Hz; a typical frequency (operation at constant speed) may be 50 Hz.

While operation at constant speed, the resonance may not be visible when performing frequency analysis. When controlling the pump (machine arrangement) at different speeds/frequencies, e.g., scanning or sampling the speed/frequency range, e.g., the operational range, the resonance may be identifiable. This may be performed in relatively short timescales (without necessity to have a phase of near-constant speed per speed value), because the method described facilitates peak detection even for changing speeds with good reliability. A short timescale may be such that during a frequency analysis time window (e.g., a time for which one FFT is performed) the window covers multiple speeds and/or operation frequencies, and/or at least 10% or at least 25% or at least 50% of the operational range (in speed and/or frequency) and/or a speed change (e.g., maximum change or average change or minimum change within the time window) of at least 10% or at least 25% or at least 50%).

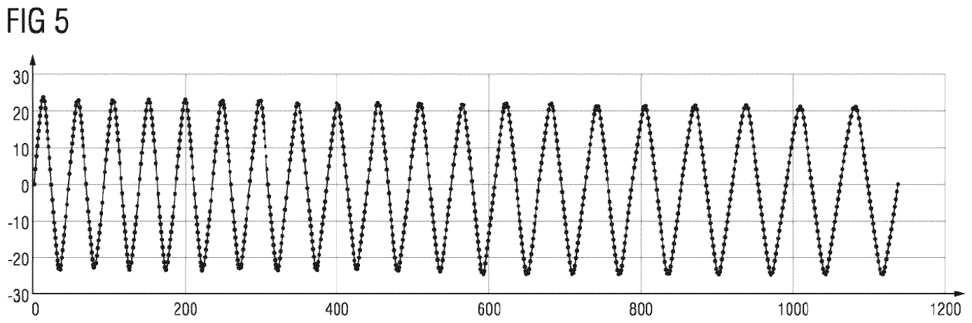

In more detail, FIG. 5 shows an exemplary diagram of obtained time domain measurement samples. The axes show current amplitude (as indication of operation speed) over sample number in time. The samples are evenly spaced in time domain. As can be seen, the speed decreases in the example; peaks to the right are farther apart than peaks on the left. In the example, there is shown the time domain current measurement with 20 periods, speed decreasing.

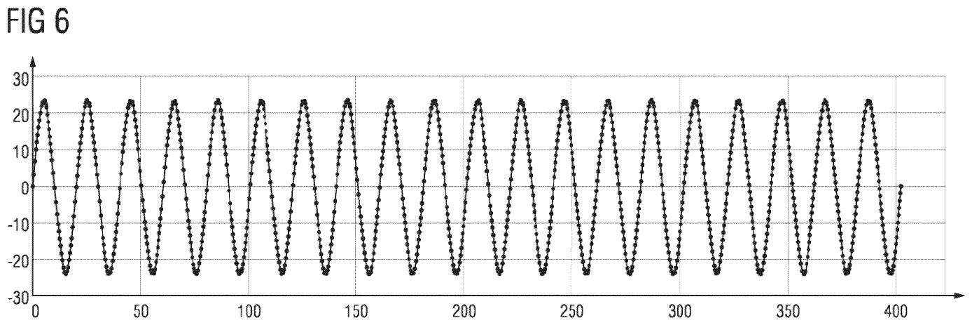

FIG. 6 shows an exemplary diagram after determining upgraded samples. Each duration between neighboring samples has been adapted according to Tadapt=T* f_{actual}(n)/F (with F=50 Hz; T may indicate the duration between two samples, e.g., between sample n-1 and n (or analogous, depending on the parametrization of n used; n may extend over the number of gaps). T may be constant for samples measured periodically. f_{actual}(n) may indicate the actual frequency at the new timing, or the old timing, or in a (e.g., small or close) environment thereof (e.g., 1/10 or smaller than the gap between samples in time domain).

Next to the current measurement, the actual frequency may be measured, for example, the inverter may provide the exact actual frequency. In particular, it is proposed changing and/or adapting the length of all time intervals between the measuring points/samples. In an alternative expression, the relationship: T_{Norm}=Tₛₐₘₚₗₑ*f_{actual}/50 Hz may be used, with T_{Norm} being another expression for T_{adapt}, and representing the length of a time interval between two samples after adaption; and Tₛₐₘₚₗₑ corresponding to T.

Accordingly, a signal is provided that may be seen as a normed 50 Hz current signal. The sampling time is not constant. Accordingly, it cannot be directly subjected to an FFT. As an alternative expression, the adaption may be written as T_{adapt}(n)=T(n)*f_{actual}(n)/F, with T(n) representing potentially non-constant time domain gap between samples. The point of time of each sample may be determined based on adding the preceding Tadapt values (representing time durations) from the starting point (e.g., earliest T(n)).

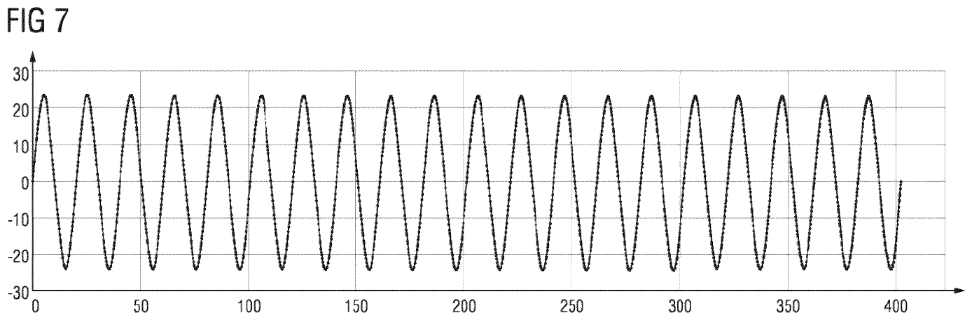

As shown in FIG. 7, recreated, normalized time domain samples are determined. In the example, linear interpolation is used to create the recreated, normalized curve with more measuring points (samples), corresponding to smaller sampling time. The time between samples (sampling time) is constant. Instead of N samples, M samples are provided. Interpolation or Estimation is used to provide sample values at the newly determined points in time; instead of linear interpolation, other interpolation methods may be used; this may be decided based on balancing computational effort with quality of the interpolation and/or estimate. This provides data on which FFT can be used. The result can be used for diagnostic purposes and/or for controlling the machine arrangement. Peaks may be identifiable like with constant speed measurement, frequency resolution may be high.

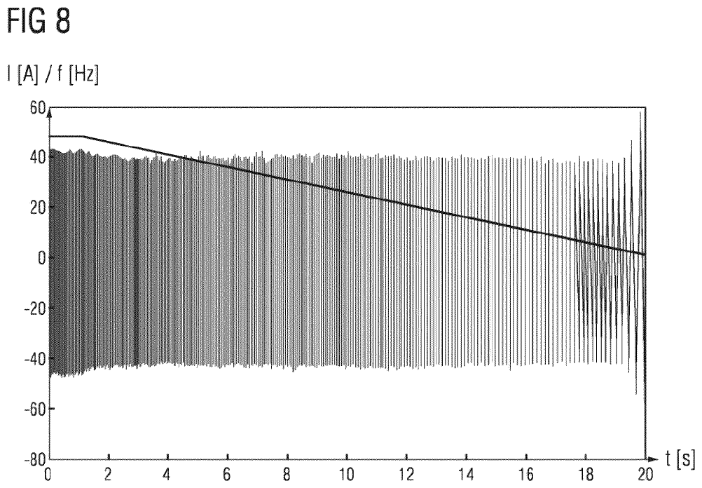

FIG. 8 shows an example of a machine arrangement spectrum and frequency, where the speed (frequency) of operation decrease, as indicated by the prominent decreasing line.

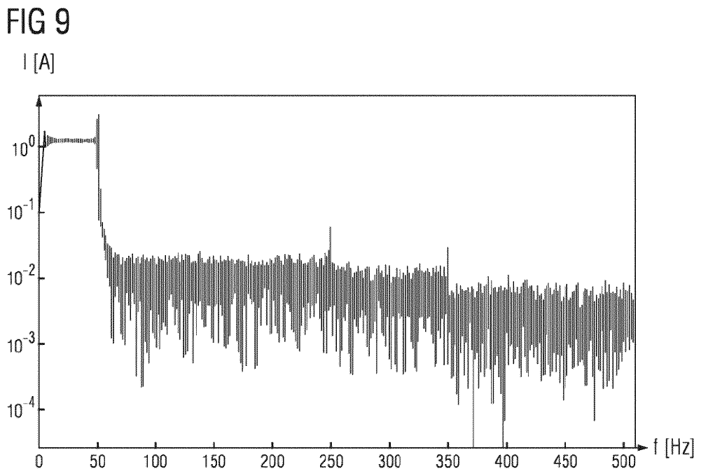

FIG. 9 shows the current frequency spectrum of the situation shown in FIG. 8 produced with an FFT using the samples originally provided. The peaks are faded/spread out significantly, which makes diagnosis and/or control difficult.

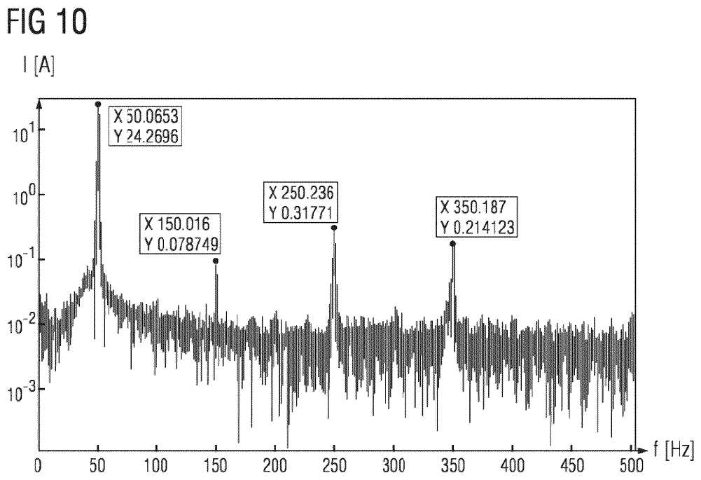

FIG. 10 shows an example of using the inventive method on the original data of FIG. 8, and performing an FFT on the recreated, normalized samples. Peaks are prominent and easily identifiable.

In general, circuitry may comprise integrated circuitry. Processing circuitry may comprise one or more processors and/or controllers (e.g., microcontrollers), and/or Application Specific Integrated Circuitry (ASICs) and/or Field Programmable Gate Array (FPGAS) , or similar. It may be considered that processing circuitry comprises, and/or is (operatively) connected or connectable to one or more memories of memory arrangements or storage media, which may be non-transitory. A storage medium or memory arrangement may comprise one or more memories. A memory may be adapted to store digital information. Examples for memories comprise volatile and non-volatile and/or non-transitory memory, and/or Random Access Memory (RAM), and/or Read-Only-Memory (ROM), and/or magnetic and/or optical memory, and/or flash memory, and/or hard disk memory, and/or EPROM or EEPROM (Erasable Programmable ROM or Electrically Erasable Programmable ROM).

Even though the present invention has been illustrated and explained in detail above with reference to the preferred embodiments, the invention is not to be construed as limited to the given examples. Variants or alternate combinations of features given in different embodiments may be derived by a subject matter expert without exceeding the scope of present invention.

Thus, while there have been shown, described and pointed out fundamental novel features of the invention as applied to a preferred embodiment thereof, it will be understood that various omissions and substitutions and changes in the form and details of the methods described and the devices illustrated, and in their operation, may be made by those skilled in the art without departing from the spirit of the invention. For example, it is expressly intended that all combinations of those elements and/or method steps that perform substantially the same function in substantially the same way to achieve the same results are within the scope of the invention. Moreover, it should be recognized that structures and/or elements and/or method steps shown and/or described in connection with any disclosed form or embodiment of the invention may be incorporated in any other disclosed or described or suggested form or embodiment as a general matter of design choice. It is the intention, therefore, to be limited only as indicated by the scope of the claims appended hereto.

1.-14. (canceled)

15. A method for analyzing a machine arrangement, the method comprising:
obtaining N time domain measurement samples at times T(n) pertaining to operation of the machine arrangement, with a typical frequency F of the operating machine arrangement, n extending over the number of samples N, and the distance between neighboring samples in time domain being T;
determining updated time domain measurement samples with timing T_{adapt}(n) of each sample based on (i) at least one of the associated T(n) and T, (ii) at least one of an actual frequency factual(n) of the analyzed machine arrangement associated to the timing T(n) and T_{adapt}(n), and (iii) F, F being a frequency correlated with at least one of (i) an occurrence of an undesirable behavior and (ii) at least one error of the machine arrangement, and the updated time domain measurement samples being normalized time domain measurement samples;
determining M recreated time domain measurement samples at times T(m) with a constant sampling period T2 from the normalized time domain measurement samples, m extending over the number of samples M and at least one of M>N and T2 being less than T; and
performing frequency analysis on the recreated time domain measurement samples.

16. The method according to claim 15, wherein the updated time domain measurement samples are determined based on the relationship T_{adapt}=T*f_{actual}(n)/F.

17. The method according to claim 15, wherein F lies in an operational range of frequencies of the machine arrangement.

18. The method according to claim 15, wherein F is 50 Hz.

19. Method according to claim 15, wherein the samples indicate at least one of (i) a current, (ii) voltage, (iii) speed and (iv) vibrational amplitude.

20. The method according to claim 15, wherein the method is performed conditioned on an acceleration threshold or speed change threshold being reached by the machine arrangement.

21. The method according to claim 15, wherein the machine arrangement operates at varying speed.

22. The method according to claim 15, wherein the machine arrangement comprises a rotational element.

23. The method according to claim 15, wherein the rotational element comprises one of a rotor, motor and generator.

24. The method according to claim 15, wherein the machine arrangement at least one of (i) comprises an AC machine and (ii) is driven by three-phase current; and wherein the samples represent a current amplitude.

25. The method according to claim 15, wherein performing frequency analysis comprises performing Fast Fourier Transform of the normalized time domain measurement samples.

26. A non-transitory computer-readable medium encoded with program code which, when executed processor, causes at least one of processing circuitry and a computer to perform the method according of claim 15.

27. A storage medium storing the computer program product according to claim 26.

28. An electronic control device comprising processing circuitry, the electronic control device being configured to:
obtain N time domain measurement samples at times T(n) pertaining to operation of the machine arrangement, with a typical frequency F of the operating machine arrangement, n extending over the number of samples N, and the distance between neighboring samples in time domain being T;
determine updated time domain measurement samples with timing T_{adapt}(n) of each sample based on (i) at least one of the associated T(n) and T, (ii) at least one of an actual frequency factual(n) of the analyzed machine arrangement associated to the timing T(n) and T_{adapt}(n), and (iii) F, F being a frequency correlated with at least one of (i) an occurrence of an undesirable behavior and (ii) at least one error of the machine arrangement, and the updated time domain measurement samples being normalized time domain measurement samples;
determine M recreated time domain measurement samples at times T(m) with a constant sampling period T2 from the normalized time domain measurement samples, m extending over the number of samples M and at least one of M>N and T2 being less than T; and
perform (A16) frequency analysis on the recreated time domain measurement samples.

29. A machine arrangement comprising an electronic control device according to claim 28.
